(19) United States
(12) Patent Application Publication
(10) Pub. No.: US 2020/0144381 A1
(43) Pub. Date: May 7, 2020

(54) LDMOS DEVICE WITH A DRAIN CONTACT STRUCTURE WITH REDUCED SIZE

(71) Applicant: Monolithic Power Systems, Inc., San Jose, CA (US)

(72) Inventors: Eric Braun, Mountain View, CA (US); Joel McGregor, Kirkland, WA (US); Jeesung Jung, San Ramon, CA (US)

(21) Appl. No.: 16/183,684

(22) Filed: Nov. 7, 2018

(51) Int. Cl. H01L 29/417; H01L 23/522; H01L 29/66; H01L 29/78

(52) U.S. Cl. CPC H01L 29/41758; H01L 23/5226; H01L 29/402; H01L 29/7816; H01L 29/66681

(57) ABSTRACT

An LDMOS device with a plurality of drain contact structures. Each drain contact structure has a drain contact, a first drain contact metal layer and a via. The drain contact is positioned above a drain region. The first drain contact metal layer is positioned above the drain contact. The via is positioned above the first drain contact metal layer. The LDMOS device has a second drain contact metal layer conductively coupled to the via of each drain contact structure.

### FIELD OF THE INVENTION

The present invention relates generally to LDMOS device, and more particularly but not exclusively to LDMOS devices with a plurality of drain contact structures.

### BACKGROUND OF THE INVENTION

It is customary for traditional power LDMOS (Lateral Diffused Metal-Oxide-Semiconductor) devices to maximize the power path metallization connectivity, specifically to maximally populate the source and drain regions with contacts and metals. This is done to minimize the resistance of the contact/metal path as well as the current density. This is generally prescriptive for better performance and reliability.

However, at increased switching frequencies and device structural densities, the switching losses due to the contact and metal parasitic capacitances can be substantially larger than the conduction losses due to the contact and metal parasitic capacitances, while the benefit due to the low current density of the fully populated metallization may be far below the reliability issue caused by the fully populated metallization.

Thus, an LDMOS device with a configuration that at least addresses the above issues is desired.

### SUMMARY

Embodiments of the present invention are directed to an LDMOS device, comprising: a source region and a drain region formed in a substrate; a gate positioned above the substrate, the gate being laterally positioned between the source region and the drain region; a plurality of drain contact structures, wherein the plurality of drain contact structures are spaced apart from each other and each drain contact structure comprises: a drain contact positioned above the drain region; a first drain contact metal layer positioned above the drain contact; and a via positioned above the first drain contact metal layer; and a second drain contact metal layer conductively coupled to the via of each drain contact structure.

Embodiments of the present invention are also directed to a method for forming an LDMOS device, comprising: forming a drift region in a substrate and a gate above the substrate; forming a body region in the substrate, wherein the body region is partially under the gate; forming a drain region in the drift region and forming a source region in the body region; forming a plurality of drain contact structures, wherein the plurality of drain contact structures are formed to be spaced apart from each other, and wherein the step of forming each drain contact structure comprises: forming a drain contact above the drain region; forming a first drain contact metal layer above the drain contact; and forming a via above the first drain contact metal layer; and forming a second drain contact metal layer above the via of each drain contact structure.

### DESCRIPTION OF THE DRAWINGS

The present invention can be further understood with reference to the following detailed description and the appended drawings, wherein like elements are provided with like reference numerals.

FIG. 1A and FIG. 1B schematically depict a novel LDMOS device 100 in accordance with an embodiment of the present invention;

FIG. 2A and FIG. 2B schematically depict a novel LDMOS device 200 in accordance with another embodiment of the present invention;

FIG. 3 illustrates an exemplary method 300 for forming an LDMOS device in accordance with an embodiment of the present invention.

### DESCRIPTION

The present invention is now described. While it is disclosed in its preferred form, the specific embodiments of the invention as disclosed herein and illustrated in the drawings are not to be considered in a limiting sense. Rather, these embodiments are provided so that this invention will be thorough and complete, and will fully convey the scope of the invention to those skilled in the art. Indeed, it should be readily apparent in view of the present description that the invention may be modified in numerous ways. Among other things, the present invention may be embodied as devices, methods, software, and so on. Accordingly, the present invention may take the form of an entirely hardware embodiment, an entirely software embodiment or an embodiment combining software and hardware aspects. The following detailed description is, therefore, not to be taken in a limiting sense.

Throughout the specification, the meaning of “a,” “an,” and “the” may also include plural references.

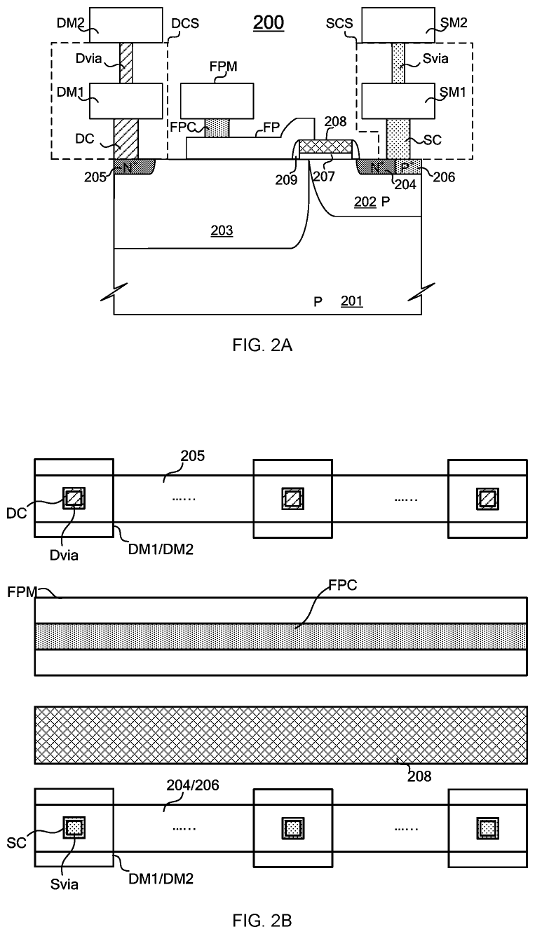

The present invention is directed to various embodiments of a novel LDMOS (Laterally Diffused Metal Oxide Semiconductor) device with novel drain contact structures and a method of making such an LDMOS device. As will be readily apparent to those skilled in the art upon a complete reading of the present application, the present method is applicable to a variety of devices, including, but not limited to, logic devices, memory devices, etc. With reference to FIGS. 2A-2B, 3 and 4, various illustrative embodiments of the devices and the method disclosed herein will now be described in more detail.

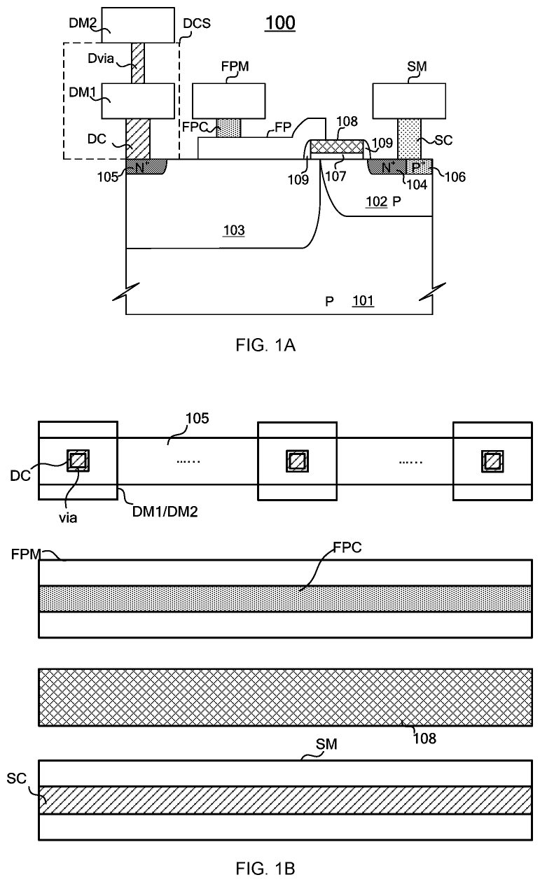

FIG. 1A and FIG. 1B schematically depict a novel LDMOS device 100 in accordance with an embodiment of the present invention. In more detail, FIG. 1A is a cross-sectional view of such an LDMOS device 100 and FIG. 1B is a schematically depicted plan view of various portions of such an LDMOS device 100. As shown in FIG. 1A, the LDMOS device 100 of FIG. 1A is illustrated to comprise a semiconducting substrate 101, such as a silicon substrate having a bulk or so-called silicon-on-insulator (SOI) configuration. Of course, the substrate 101 may be comprised of a variety of materials other than silicon, depending upon the particular application. In one illustrative embodiment, the LDMOS device 100 disclosed herein is also configured to comprise a P-well region 102, an N-doped drift region 103, an N+ doped source region 104, an N+ doped drain region 105 and a P+ doped well tap 106 that may be formed in the substrate 101 by traditional techniques. In one embodiment, the N+ doped drain region 105 or the N+ doped source region 104 may have a shape of a stripe along the longitudinal direction.

Persons of ordinary skill in the art will recognize that the N type LDMOS device 100 comprising the above various regions with the illustrative doping conductivity types is illustrated for exemplary purpose, the structures presented in the present invention may be also applied in a P type LDMOS device with the various regions having opposite conductivity types to that of the N type LDMOS device 100.

The illustrative LDMOS device 100 is further configured to comprise a gate which comprises a gate insulation layer 107, a gate electrode 108 and sidewall spacers 109. The gate is generally laterally positioned between the source region 104 and the drain region 105 so as to establish a channel under the gate electrode 108. Persons of ordinary skill in the art will recognize that in one embodiment, the spacers 109 may be omitted from the gate, yet in another embodiment, more regions may be comprised by the gate, such as a plurality of metal silicide regions.

FIG. 1B is a schematically depicted plan view of portions of the LDMOS device 100 depicted in FIG. 1A. As shown in FIG. 1A and FIG. 1B, the LDMOS device 100 is further configured to comprise a plurality of drain contact structures DCS and a second drain contact metal layer DM2 for electrically coupling the N+ doped drain region 105 to an external applying voltage (not shown). Each of the plurality of drain contact structures DCS is configured to comprise a drain contact DC positioned above and electrically coupled to the N+ doped drain region 105, a first drain contact metal layer DM1 positioned above and electrically coupled to the drain contact DC, a via Dvia positioned above and electrically coupled to the first drain contact metal layer DM1. In the embodiment as shown in FIGS. 1A and 2B, the first drain contact metal layer DM1 extends laterally beyond both sides of the drain contact DC. However, in another embodiment, the first drain contact metal layer DM1 may extend equal to both sides of the drain contact DC laterally. In yet another embodiment, the first drain contact metal layer DM1 may be inside the drain contact DC laterally. As shown in FIG. 1B, the plurality of drain contact structures DCS are spaced apart from each other. In an embodiment, the space between the two adjacent drain contact structures DCS is larger than the size of each of the drain contact structure, for example, the space between the two adjacent drain contact structures DCS may be designed to be about nine times of the size of each of the drain contact structure. In an embodiment, the plurality of drain contact structures DCS have the same shape and size although different shape or size with the same functionality may be possible in other embodiments. In an embodiment, the plurality of the drain contact structures DCS are arranged in a line along the longitudinal direction. The second drain contact metal layer DM2 is positioned above and electrically coupled to the plurality of drain contact structures DCS for coupling all the discontinuous drain contact structures DCS to a common external applying voltage. In the illustrative embodiment, the second drain contact metal layer DM2 has the same width as that of the first drain contact metal layer DM1 in the lateral direction. However, persons of ordinary skill in the art will recognize that the second drain contact metal layer DM2 may be a little wider or narrower than the first drain contact metal layer DM1 in the lateral direction in another embodiment.

Compared with the traditional drain contact structure with a long strip of drain contact and a long strip of drain contact metal layer covering the N+ doped drain region in the whole longitudinal direction, the total size of all of the plurality of the drain contact structures DCS of the present invention is largely reduced. Associated with the reduction of the size of the drain contact metal and of the drain contact operating as parasitic parallel plates, the fringing fields between the drain contact metal and the drain contact to other nearby metal, poly and silicon conductors, etc. are largely reduced, and thus so are the associated parasitic capacitances induced thereby. Reducing these parasitic capacitances has the benefit of reduced power loss and enhanced efficiency gain for switching operation when the LDMOS device is used as a switching component.

As shown in FIG. 1A and FIG. 1B, the LDMOS device 100 may be further configured to comprise a field plate FP, such as a silicide field plate, which is positioned above the N-doped drift region 103 and between the N+ doped drain region 105 and the gate of the LDMOS device 100. In the illustrative embodiment, the field plate FP extends to but separated from the N+ doped drain region 105 and is positioned above a portion of the gate electrode 108. In another embodiment, depending upon the particular design, the field plate FP may extend all of the way to the N+ doped drain region 105. In yet another embodiment, the field plate FP do not necessarily positioned above a portion of the gate electrode 108. In some applications, the field plate FP may be formed so as to have a greater thickness than traditional prior art field plates so as to insure that the field plate contact FPC that is positioned above the field plate FP (will be apparent later) do not reach the underlying N-drift region 103.

In one embodiment, the LDMOS device 100 may comprise a field plate stop layer positioned between the substrate 101 and the field plate FP to insulate the field plate FP and the substrate 101. In one embodiment, the field plate stop layer may be a pad oxide layer, such as a layer of silicon dioxide.

Further refer to FIG. 1A and FIG. 1B, the LDMOS device 100 is further configured to comprise a field plate contact FPC positioned above the field plate FP and a field plate contact metal layer FPM positioned above the field plate contact FPC for electrically coupling the field plate FP to an external applying voltage. As shown in FIG. 1B, the field plate contact metal layer FPM extends from one end of the field plate contact FPC all of the way to the other end of the field plate contact FPC in the longitudinal direction. But of course, field plate contact metal layers with other shapes may be complemented in other embodiment.

In the LDMOS device 100, the field plate contact FPC acts to position a lower electrical potential nearer to the N+ doped drain region 105 of the LDMOS device 100 and thereby more effectively force the high electrical fields that are normally present near the drain side edge of the gate electrode 108 farther away from the gate electrode 108 toward the N+ doped drain region 105. In this manner, the peak electric field is effectively reduced and equivalently, the breakdown voltage of the LDMOS device 100 is increased.

With the drain contact structures DCS of the present invention, the reduction of the size of the first drain contact metal layer DM1 and of the drain contact DC enables the reduction of the fringing fields between the first drain contact metal layer DM1 and the drain contact DC to the field plate contact FPC and to the field plate contact metal layer FPM, as a result, the associated parasitic capacitances induced thereby are also reduced. Reducing these parasitic capacitances has the benefit of reduced power loss and enhanced efficiency gain for switching operation when the LDMOS device is used as a switching component.

Persons of ordinary skill in the art will recognize that the field plate FP and the associated field plate contact FPC and field plate contact metal layer FPM are comprised in the LDMOS device 100 in the illustrative embodiment of FIG. 1A and FIG. 1B, however, these parts may be omitted in another embodiment and the present invention still applies without these parts.

The LDMOS device 100 is further configured to comprise a source contact SC electrically coupled to the source region 104. In the illustrative embodiment of FIG. 1A, the source contact SC is also positioned on a portion of the P+ doped well tap 106. Furthermore, a source metal layer SM is comprised to be positioned on the source contact SC. As shown in FIG. 1B, the source metal layer SM extends from one end of the source contact SC all of the way to the other end of the source contact SC in the longitudinal direction. The source contact SC and the source metal layer SM are coupled to a relatively low voltage (“V_{LOW}”), while the drain contact structure DCS is coupled to a relatively higher voltage (“V_{HIGH}”). In one illustrative embodiment, the V_{LOW} voltage may be about 0 volts while the V_{HIGH} voltage may be about dozens of volts. Of course, the absolute values for the applied voltages V_{LOW} and V_{HIGH} may vary depending upon the particular application. In the depicted example, the source contact SC and the source metal layer SM are electrically coupled to the source region 104 and the P+ doped well tap 106 for coupling the source region 104 and the P+ doped well tap 106 to the same relatively low voltage. However, persons of ordinary skill in the art will recognize that in yet another embodiment, the P+ doped well tap 106 may have a separate contact as well as a separate metal layer being formed thereon other than sharing the source contact SC and the source metal layer SM with the source region 104. And the separate contact and metal layer are coupled to another relatively low voltage differentiating from the voltage applied on the source contact SC and the source metal layer SM, as compared to the voltage applied to the drain contact DC and the drain metal layer DM1.

FIG. 2A and FIG. 2B schematically depict a novel LDMOS device 200 in accordance with another embodiment of the present invention. The LDMOS device 200 has a similar structure as that of the LDMOS device 100, thus, only the different parts of the LDMOS device 200 will be focused herein and the same parts will not be described for simplicity purpose. Refer to FIG. 2A and FIG. 2B, the LDMOS device 200 comprises a plurality of source contact structure SCS with each having a similar structure as that of the drain contact structure DCS. In detail, each of the source contact structure SCS is configured to comprise a source contact SC positioned above and electrically coupled to the source region 204 and the P+ doped well tap 206, a first source contact metal layer SM1 positioned above and electrically coupled to the source contact SC, a via Svia positioned above and electrically coupled to the first source contact metal layer SM1. As shown in FIG. 2B, the plurality of source contact structures SCS are spaced apart from each other. In an embodiment, the space between the two adjacent source contact structures SCS is larger than the size of each of the source contact structure, for example, the space between the two adjacent source contact structures SCS may be designed to be about nine times of the size of each of the source contact structure SCS. In an embodiment, the plurality of source contact structures SCS have the same shape and size although different shape or size with the same functionality may be possible in other embodiments. In an embodiment, the plurality of the source contact structures SCS are arranged in a line along the longitudinal direction. The second source contact metal layer SM2 is positioned above and electrically coupled to the plurality of source contact structures SCS for coupling all the discontinuous source contact structures SCS to a common external applying voltage. In the illustrative embodiment, the second source contact metal layer SM2 has the same width as that of the first source contact metal layer SM1 in the lateral direction. However, persons of ordinary skill in the art will recognize that the second source contact metal layer SM2 may be a little wider or narrower than the first source contact metal layer SM1 in the lateral direction in another embodiment.

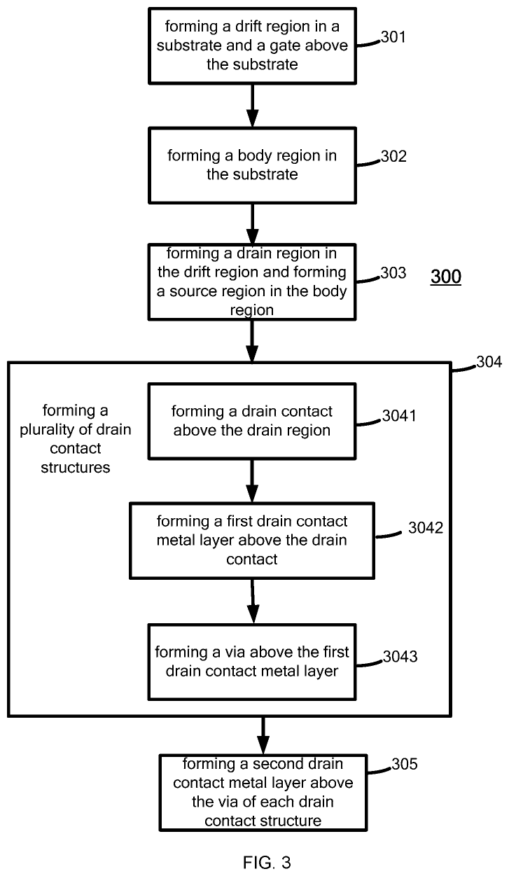

As shown in FIGS. 2A and 3B, the source metal layer SM1 extends laterally beyond both sides of the source contact SC. However, in another embodiment, the source metal layer SM1 may extend equal to both sides of the source contact SC laterally. In yet another embodiment, the source metal layer SM1 may be inside the source contact SC laterally.

In the depicted example, the source contact SC and the source metal layer SM are electrically coupled to the source region 204 and the P+ doped well tap 206 for coupling the source region 204 and the P+ doped well tap 206 to the same relatively low voltage. However, persons of ordinary skill in the art will recognize that in yet another embodiment, the P+ doped well tap 206 may have a separate contact as well as a separate metal layer being formed thereon other than sharing the source contact SC and the source metal layer SM with the source region 204. And the separate contact and metal layer are coupled to another relatively low voltage differentiating from the voltage applied on the source contact SC and the source metal layer SM, as compared to the voltage applied to the drain contact DC and the drain metal layer DM1.

Compared with the traditional source contact structure with a long strip of source contact and a long strip of source contact metal layer covering the N+ doped source region in the whole longitudinal direction, the total size of all of the plurality of the source contact structures SCS of the present invention is largely reduced. Associated with the reduction of the size of the source contact metal and of the source contact operating as parasitic parallel plates, the fringing fields between the source contact metal and the source contact to other nearby metal, poly and silicon conductors, etc. are largely reduced, and thus so are the associated parasitic capacitances induced thereby. Reducing these parasitic capacitances has the benefit of reduced power loss and enhanced efficiency gain for switching operation when the LDMOS device is used as a switching component.

FIG. 3 illustrates an exemplary method 300 for forming an LDMOS device in accordance with an embodiment of the present invention. As shown in FIG. 3, the method 300 for forming the LDMOS device is illustrated to comprise steps 301-305. In detail, step 301 comprising forming a drift region in a substrate and a gate above the substrate. Step 302 comprises forming a body region in the substrate, wherein the body region is formed partially under the gate. Step 303 comprises forming a drain region in the drift region and forming a source region in the body region. Step 304 comprises forming a plurality of drain contact structures, wherein the plurality of drain contact structures are formed to be spaced apart from each other. In more detail, the step 304 comprises steps 3041-3043. In step 3041, a drain contact is formed above the drain region. In step 3042, a first drain contact metal layer is formed above the drain contact. And in step 3043, a via is formed above the first drain contact metal layer. Step 305 comprises forming a second drain contact metal layer above the via of each drain contact structure.

In one embodiment, the plurality of drain contact structures are formed in a line along the longitudinal direction. In another embodiment, the plurality of drain contact structures are formed to have the same size and the space between every two adjacent drain contact structures are formed to be nine times of the size of the drain contact structure. In yet another embodiment, each of the plurality of drain contact structures is formed to be spaced apart from the gate.

In one embodiment, the method 300 further comprises forming a plurality of source contact structures with each being spaced apart from the gate, wherein the plurality of source contact structures are formed to be spaced apart from each other. The step of forming each source contact structure comprises: forming a source contact above the source region; forming a first source contact metal layer above the source contact; and forming a via above the source contact metal layer. The method 300 further comprises forming a second source contact metal layer above the via of each source contact structure.

In one embodiment, the plurality of source contact structures are formed in a line along the longitudinal direction. In another embodiment, the plurality of source contact structures are formed to have the same size and the space between every two adjacent source contact structures are formed to be nine times of the size of the drain contact structure. In yet another embodiment, each of the plurality of source contact structures is formed to be spaced apart from the gate.

In one embodiment, the method 300 further comprises forming a field plate structure separated from the plurality of drain contact structures. The step of forming the field plate structure comprises: forming a field plate above the substrate, wherein the field plate is formed between the gate and the drain region; forming a field plate contact above the field plate; and forming a field plate contact metal layer above the field plate contact.

It will be appreciated by persons skilled in the art that the present invention is not limited to what has been particularly shown and described herein above. Rather the scope of the present invention is defined by the claims and includes both combinations and sub-combinations of the various features described hereinabove as well as variations and modifications thereof which would occur to persons skilled in the art upon reading the foregoing description and which are not in the prior art.

1. An LDMOS device, comprising:
a source region and a drain region formed in a substrate;
a gate positioned above the substrate, the gate being laterally positioned between the source region and the drain region;
a plurality of drain contact structures, wherein the plurality of drain contact structures are spaced apart from each other and each drain contact structure comprises:
a drain contact positioned above the drain region;
a first drain contact metal layer positioned above the drain contact; and
a via positioned above the first drain contact metal layer; and
a second drain contact metal layer conductively coupled to the via of each drain contact structure.

2. The LDMOS device of claim 1, wherein the plurality of drain contact structures are arranged in a line along the longitudinal direction.

3. The LDMOS device of claim 2, wherein the plurality of drain contact structures have the same size and the space between every two adjacent drain contact structures are nine times of the size of the drain contact structure.

4. The LDMOS device of claim 1, wherein each of the plurality of drain contact structures is spaced apart from the gate.

5. The LDMOS device of claim 1, wherein the LDMOS device further comprises:
a plurality of source contact structures, wherein the plurality of source contact structures are spaced apart from each other and each source contact structure comprises:
a source contact positioned above the source region;
a first source contact metal layer positioned above the source contact; and
a via positioned above the first source contact metal layer; and
a second source contact metal layer conductively coupled to the via of each source contact structure.

6. The LDMOS device of claim 5, wherein the plurality of source contact structures are arranged in a line along the longitudinal direction.

7. The LDMOS device of claim 6, wherein the plurality of source contact structures have the same size and the space between every two adjacent source contact structures are nine times of the size of the source contact structure.

8. The LDMOS device of claim 5, wherein each of the plurality of source contact structures is spaced apart from the gate.

9. The LDMOS device of claim 1, wherein the LDMOS device further comprises a field plate structure separated from the plurality of drain contact structures, and wherein the field plate structure comprises:
a field plate positioned above the substrate, wherein the field plate is positioned between the gate and the drain region;
a field plate contact positioned above the field plate; and
a field plate contact metal layer conductively coupled to the field plate contact.

10. A method for forming an LDMOS device, comprising:
forming a drift region in a substrate and a gate above the substrate;
forming a body region in the substrate, wherein the body region is partially under the gate;
forming a drain region in the drift region and forming a source region in the body region;
forming a plurality of drain contact structures, wherein the plurality of drain contact structures are formed to be spaced apart from each other, and wherein the step of forming each drain contact structure comprises:
forming a drain contact above the drain region;
forming a first drain contact metal layer above the drain contact; and
forming a via above the first drain contact metal layer; and
forming a second drain contact metal layer above the via of each drain contact structure.

11. The method of claim 10, wherein the plurality of drain contact structures are formed in a line along the longitudinal direction.

12. The method of claim 11, wherein the plurality of drain contact structures are formed to have the same size and the space between every two adjacent drain contact structures are formed to be nine times of the size of the drain contact structure.

13. The method of claim 10, wherein each of the plurality of drain contact structures is formed to be spaced apart from the gate.

14. The method of claim 10, wherein the method further comprises:
forming a plurality of source contact structures with each being spaced apart from the gate, wherein the plurality of source contact structures are formed to be spaced apart from each other, and wherein the step of forming each source contact structure comprises:
forming a source contact above the source region;
forming a first source contact metal layer above the source contact; and
forming a via above the source contact metal layer; and
forming a second source contact metal layer above the via of each source contact structure.

15. The method of claim 14, wherein the plurality of source contact structures are formed in a line along the longitudinal direction.

16. The method of claim 15, wherein the plurality of source contact structures are formed to have the same size and the space between every two adjacent source contact structures are formed to be nine times of the size of the source contact structure.

17. The method of claim 14, wherein each of the plurality of source contact structures is formed to be spaced apart from the gate.

18. The method of claim 10, wherein the method further comprises forming a field plate structure separated from the plurality of drain contact structures, and wherein the step of forming the field plate structure comprises:
forming a field plate above the substrate, wherein the field plate is formed between the gate and the drain region;
forming a field plate contact above the field plate; and
forming a field plate contact metal layer above the field plate contact.
